(19) United States
(12) Patent Application Publication
(10) Pub. No.: US 2025/0030320 A1
(43) Pub. Date: Jan. 23, 2025

(54) FILTER COMPONENT

(71) Applicant: DENSO CORPORATION, Kariya-city (JP)

(72) Inventors: Toshitada SANZEN, Kariya-city (JP); Koji SAKAI, Kariya-city (JP); Yuki IKEDA, Kariya-city (JP)

(73) Assignee: DENSO CORPORATION, Kariya-city (JP)

(21) Appl. No.: 18/907,869

(22) Filed: Oct. 7, 2024

Related U.S. Application Data
(63) Continuation of application No. PCT/JP2023/016164, filed on Apr. 24, 2023.

(30) Foreign Application Priority Data
Apr. 29, 2022 (JP) 2022-075597

(51) Int. Cl. H02K 11/02; B60L 1/00; B60L 50/51; B60L 50/60; H02K 11/00

(52) U.S. Cl. CPC H02K 11/02; B60L 1/003; B60L 50/51; B60L 50/60; H02K 11/0094; B60L 2210/40

(57) ABSTRACT

A filter component is adapted to an electrical system having first and second electric apparatuses. The filter component has a resistive element and first, second, third and fourth windings. The first electric apparatus has a power terminal being a first power terminal and another power terminal being a second power terminal. The second electric apparatus has a power terminal being a third power terminal and another power terminal being a fourth power terminal. The first and second windings are connected in series, and the third and fourth windings are connected in series. The first and third windings form a common-mode inductor suppressing a common-mode noise current. The first to fourth windings form a differential-mode inductor suppressing a differential-mode noise current. The resistive element is connected in parallel across at least one of the first to fourth windings.

### CROSS REFERENCE TO RELATED APPLICATIONS

The present application is a continuation application of International Patent Application No. PCT/JP2023/016164 filed on Apr. 24, 2023, which designated the U.S. and claims the benefit of priority from Japanese Patent Application No. 2022-075597 filed on Apr. 29, 2022. The entire disclosures of all of the above applications are incorporated herein by reference.

### TECHNICAL FIELD

The present disclosure relates to a filter component.

### BACKGROUND

A filter component may form a differential mode inductor and a common mode inductor in an integrated magnetic core.

### SUMMARY

The present disclosure describes a filter component adapted to an electrical system, and further describes that the filter component includes a magnetic core, first to fourth windings wound around the magnetic core, and a resistive element.

### BRIEF DESCRIPTION OF DRAWINGS

Objects, features and advantages of the present disclosure will become more apparent from the following detailed description made with reference to the accompanying drawings. In the drawings:

FIG. 1 is a block diagram that illustrates the overall configuration of a high-voltage system in the first embodiment, and that illustrates a circuit configuration where a resistive element is connected in parallel with the winding of a differential mode inductor in a filter component;

FIG. 2 is a diagram that illustrates the details of the configuration of the filter component in the first embodiment shown in FIG. 1, and that illustrates the function of suppressing a differential mode ripple current and a common mode noise current;

FIG. 3 is an electrical circuit diagram showing an equivalent circuit of the filter component in the first embodiment shown in FIG. 1;

FIG. 4 is a block diagram that illustrates the overall configuration of a high-voltage system in a comparative example, and that illustrates the resonance occurring in the TT-type filter having two smoothing capacitors and the differential mode inductor of the filter component;

FIG. 5 is a diagram that illustrates the transfer characteristics of the TT-type filter having the differential mode inductor and the two smoothing capacitors in the high-voltage system in the comparative example;

FIG. 6 is a diagram that illustrates the transfer characteristics of the TT-type filter having the differential mode inductor and the two smoothing capacitors in the high-voltage system related to the first embodiment shown in FIG. 1;

FIG. 7 is a diagram that illustrates the details of the configuration of the filter component in a second embodiment, and that reinforces in explaining the circuit configuration where two resistive elements are connected in parallel to the differential mode inductor;

FIG. 8 is an electrical circuit diagram that illustrates the equivalent circuit of the filter component in the second embodiment of FIG. 7, and that illustrates the arrangement relationship between the resistive elements and the windings;

FIG. 9 is a diagram that illustrates the details of the configuration of the filter component in a third embodiment, and that illustrates the circuit configuration where one resistive element is connected in parallel to the differential mode inductor;

FIG. 10 is an electrical circuit diagram that illustrates the equivalent circuit of the filter component in the third embodiment shown in FIG. 9, and that illustrates the arrangement relationship between the resistive element and the windings;

FIG. 11 is a diagram that illustrates the details of the configuration of the filter component in a fourth embodiment, and that illustrates a circuit configuration in which a resistive element is connected in parallel to a differential mode inductor;

FIG. 12 is a diagram that illustrates the details of the configuration of the filter component in a fifth embodiment, and that illustrates the circuit configuration where a resistive element is connected in parallel to the differential mode inductor;

FIG. 13 is a diagram that illustrates the details of the configuration of the filter component in a sixth embodiment, and that illustrates the circuit configuration where a resistive element is connected in parallel to the differential mode inductor;

FIG. 14 is a diagram that illustrates the details of the configuration of the filter component in a seventh embodiment, and that illustrates the circuit configuration where a resistive element is connected in parallel to the differential mode inductor;

FIG. 15 is a diagram that illustrates the details of the configuration of the filter component in an eighth embodiment, and that illustrates the circuit configuration where a resistive element is connected in parallel to the differential mode inductor; and

FIG. 16 is a diagram that illustrates the details of the configuration of the filter component in the ninth embodiment, and that illustrates that the resistive element is a thermistor.

### DETAILED DESCRIPTION

The inventors in the present application have considered disposing a filter component between a main inverter and an auxiliary inverter in a high-voltage system of an electric vehicle. The main inverter and the auxiliary inverter are connected in parallel to a high-voltage battery. A smoothing capacitor is connected to the main inverter to stabilize a power supply voltage output from the high-voltage battery. A smoothing capacitor that stabilizes the power supply voltage output from the high-voltage battery is connected to the auxiliary inverter.

A main smoothing capacitor, an auxiliary smoothing capacitor, and a differential mode inductor form a TT-type filter.

However, if the frequency of the differential mode ripple current (i.e., noise current) generated due to the switching operation of the main inverter matches the resonant frequency of the TT-type filter (i.e., filter circuit), resonance occurs in the TT-type filter, causing an excessive current to flow into the auxiliary smoothing capacitor. Therefore, a fault may occur in the auxiliary smoothing capacitor.

According to an aspect of the present disclosure, a filter component is adapted to an electrical system. The electrical system has a first smoothing capacitor, a second smoothing capacitor, a first electric apparatus, and a second electric apparatus. The first electric apparatus and the second electric apparatus are connected in parallel to a battery and operated by an output power of the battery. The first smoothing capacitor stabilizes a power supply voltage supplied from the battery to the first electric apparatus. The second smoothing stabilizes the power supply voltage supplied from the battery to the second electric apparatus. The filter component includes a magnetic core, first to fourth windings, a resistive element. The magnetic core includes: an outer core surrounding two empty spaces and having a circulating magnetic circuit for circulating a magnetic flux; and a short-circuit core located between the two empty spaces and having a short-circuit magnetic circuit that allows the magnetic flux to flow through a location between two parts of the outer core. The first to fourth windings are wound around the magnetic core to generate the magnetic flux that flows through the circulating magnetic circuit and the magnetic flux that flows through the short-circuit magnetic circuit. The battery has two electrodes being a first electrode and a second electrode, respectively. The first electric apparatus has a power terminal being a first power terminal connected to the first electrode of the battery, and has another power terminal being a second power terminal connected to the second electrode of the battery. The second electric apparatus has a power terminal being a third power terminal connected to the first electrode of the battery, and has another power terminal being a fourth power terminal connected to the second electrode of the battery. The first winding and the second winding are connected in series between the first power terminal and the third power terminal. The third winding and the fourth winding are connected in series between the second power terminal and the fourth power terminal. The first winding and the third winding form a common-mode inductor suppresses a common-mode noise current flowing between the first power terminal and the third power terminal as well as between the second power terminal and the fourth power terminal. The first winding, the second winding, the third winding, and the fourth winding form a differential-mode inductor that suppresses a differential-mode noise current flowing between the first power terminal and the third power terminal as well as between the second power terminal and the fourth power terminal. The first to fourth windings, the first and second smoothing capacitors form a filter circuit. The resistive element is connected in parallel across at least one of the first winding, the second winding, the third winding, or the fourth winding, and is configured to suppress resonance in the filter circuit.

Therefore, from this perspective, it is possible to provide a filter component that suppresses the occurrence of resonance in the filter circuit having the two smoothing capacitors and the differential mode inductor.

According to another aspect of the present disclosure, a filter component is adapted to an electrical system. The electrical system has a first smoothing capacitor, a second smoothing capacitor, a first electric apparatus, and a second electric apparatus. The first electric apparatus and the second electric apparatus are connected in parallel to a battery and operated by an output power of the battery. The first smoothing capacitor stabilizes a power supply voltage supplied from the battery to the first electric apparatus. The second smoothing stabilizes the power supply voltage supplied from the battery to the second electric apparatus. The filter component includes a magnetic core, first to third windings, a resistive element. The magnetic core includes: an outer core surrounding two empty spaces and having a circulating magnetic circuit for circulating a magnetic flux; and a short-circuit core located between the two empty spaces and having a short-circuit magnetic circuit that allows the magnetic flux to flow through a location between two parts of the outer core. The first to third windings are wound around the magnetic core to generate the magnetic flux that flows through the circulating magnetic circuit and the magnetic flux that flows through the short-circuit magnetic circuit. The battery has two electrodes being a first electrode and a second electrode, respectively. The first electric apparatus has a power terminal being a first power terminal connected to the first electrode of the battery, and has another power terminal being a second power terminal connected to the second electrode of the battery. The second electric apparatus has a power terminal being a third power terminal connected to the first electrode of the battery, and has another power terminal being a fourth power terminal connected to the second electrode of the battery. The first winding and the second winding are connected in series between the first power terminal and the third power terminal. The third winding is connected in series between the second power terminal and the fourth power terminal. The first winding and the third winding form a common-mode inductor that suppresses a common-mode noise current flowing between the first power terminal and the third power terminal as well as between the second power terminal and the fourth power terminal. The first winding, the second winding, and the third winding form a differential-mode inductor that suppresses a differential-mode noise current flowing between the first power terminal and the third power terminal as well as between the second power terminal and the fourth power terminal. The first to third windings, the first and second smoothing capacitors form a filter circuit. The resistive element is connected in parallel across at least one of the first winding, the second winding, or the third winding, and suppresses resonance in the filter circuit.

From this perspective, it is possible to provide a filter component designed to suppress the occurrence of resonance in the filter circuit having the two smoothing capacitors and the differential mode inductor.

Embodiments of the present disclosure will be described below with reference to the drawings. In the following embodiments, the same or equivalent portions are denoted by the same reference numerals in the drawings in order to simplify the description.

### First Embodiment

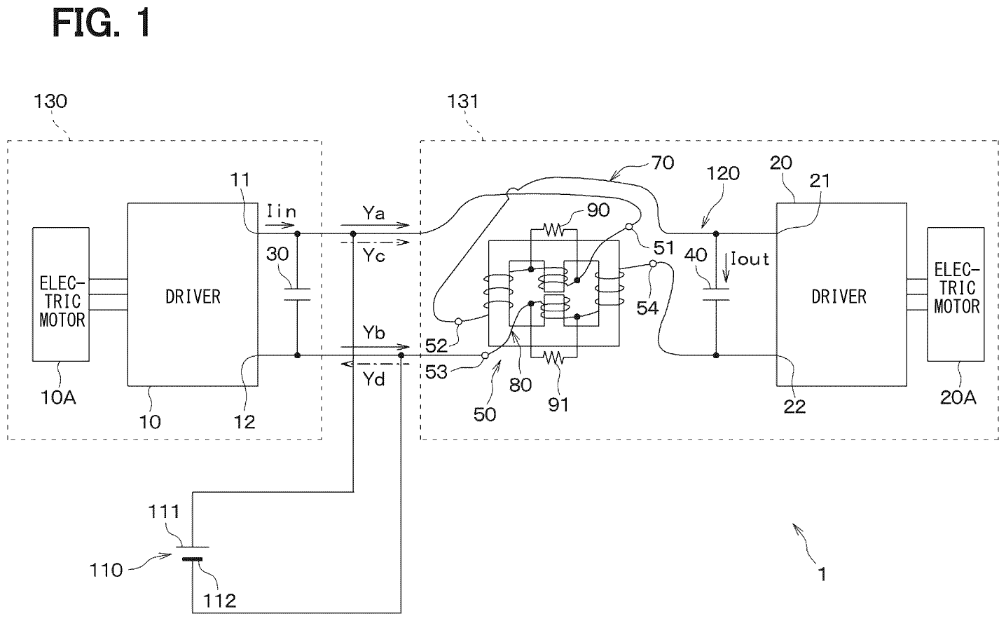

FIG. 1 illustrates the configuration of a high-voltage system 1 of an electric vehicle according to a first embodiment. The high-voltage system 1, as shown in FIG. 1, is an electrical system including drivers 10 and 20, smoothing capacitors 30 and 40, and a filter component 50. Each of the drivers 10 and 20 may also be referred to as a drive device or an electric apparatus in the present disclosure.

The driver 10, as the first electric apparatus, is an inverter equipped with multiple switching elements. The driver 10 drives an electric motor 10A being a main electric motor through the switching operation of these multiple switching elements. The electric motor 10A according to the present embodiment is a traction motor for an electric vehicle.

The driver 20, as the second electric apparatus, is an inverter equipped with multiple switching elements. The driver 20 drives an electric motor 20A as an auxiliary electric motor through the switching operation of these multiple switching elements. In this embodiment, the electric motor 20A is a motor that drives an air conditioning compressor. The drivers 10 and 20 are connected in parallel to a high-voltage battery 110. The high-voltage battery 110 is a battery having two electrodes, a positive electrode 111 and a negative electrode 112.

The smoothing capacitor 30 is the first smoothing capacitor connected between power terminals 11 and 12 of the driver 10. The smoothing capacitor 30 stabilizes the voltage output from the high-voltage battery 110 to the power terminals 11 and 12 of the driver 10.

The power terminal 11 of the driver 10 is the first power terminal connected to the positive electrode 111 (i.e., the first electrode) of the high-voltage battery 110. The power terminal 12 of the driver 10 is the second power terminal connected to the negative electrode 112 (i.e., the second electrode) of the high-voltage battery 110.

The smoothing capacitor 40 is the second smoothing capacitor connected between power terminals 21 and 22 of the driver 20. The smoothing capacitor 40 stabilizes the voltage output from the high-voltage battery 110 to the power terminals 21 and 22. The power terminal 21 of the driver 20 is the third power terminal connected to the positive electrode 111 of the high-voltage battery 110. The power terminal 22 of the driver 20 is the fourth power terminal connected to the negative electrode 112 of the high-voltage battery 110.

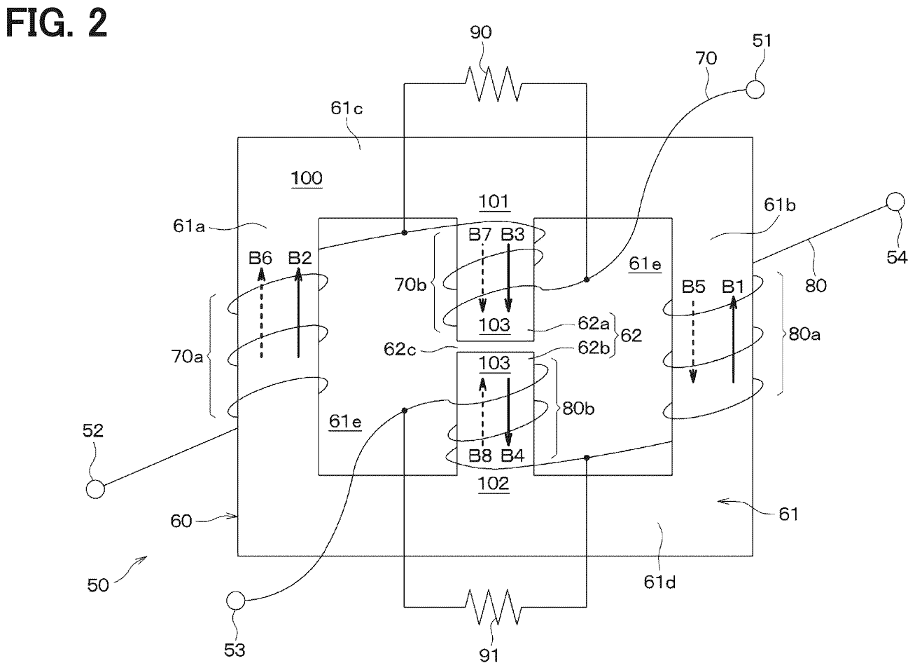

As shown in FIG. 2, the filter component 50 includes a magnetic core 60, windings 70 and 80, and resistive elements 90 and 91. Each of the resistive elements 90 and 91 may be simply referred to as a resistor in the present disclosure.

The magnetic core 60 includes an outer core 61 and a short-circuit core 62. The outer core 61 and the short-circuit core 62 are integrated together by a magnetic material such as ferrite. The outer core 61 is formed so as to surround the two voids 61e to construct a circulating magnetic path 100 through which a magnetic flux circulates. Specifically, the outer core 61 includes a left core 61a, a right core 61b, an upper core 61c, and a lower core 61d, which together form a closed magnetic path 100.

The left core 61a is positioned on the left side in FIG. 2 relative to two empty spaces 61e. The right core 61b is positioned on the right side in FIG. 2 relative to the two empty spaces 61e. The upper core 61c is positioned above the two empty spaces 61e in FIG. 2. The lower core 61d is positioned below the two empty spaces 61e in FIG. 2. The two empty spaces may also be referred to as two empty gaps or two gaps.

The left core 61a is connected to both the upper core 61c and the lower core 61d. The right core 61b is connected to the upper core 61c and the lower core 61d.

The short-circuit core 62 is formed to magnetically connect two parts 101 and 102 of the outer core 61, thereby forming a short-circuit magnetic path 103 that allows the magnetic flux to pass between the two parts 101 and 102. The short-circuit magnetic path 103 is positioned between the two empty spaces 61e. The short-circuit core 62 includes an upper core 62a and a lower core 62b.

The upper core 62a is formed to protrude from the part 101 of the upper core 61c towards the lower core 61d. The lower core 62b is formed to protrude from the part 102 of the lower core 61d towards the upper core 61c.

Between the upper core 62a and the lower core 62b, a gap 62c (i.e., a magnetic gap) is provided. The gap 62c prevents the magnetic core 60 from becoming magnetically saturated due to the magnetic flux generated by the direct current flowing through the windings 70 and 80. The gap 62c may also be referred to as an empty gap or an empty space.

The windings 70 and 80 are each having a conductive wire made of a metal material such as copper, wound around the core. The winding 70 includes windings 70a and 70b, which are connected in series between the power terminal 11 of the driver 10 and the power terminal 21 of the driver 20. The winding 70a is a second winding wound around the left core 61a. The winding 70b is a first winding wound around the upper core 62a. In the present disclosure, the power terminal may also be referred to as a power supply terminal.

The winding 80 includes windings 80a and 80b, which are connected in series between the power terminal 12 of the driver 10 and the power terminal 22 of the driver 20. The winding 80a is a fourth winding wound around the right core 61b. The winding 80b is a third winding wound around the lower core 62b.

The windings 70a and 80a form a common-mode inductor 140. The common-mode inductor 140 suppresses the flow of common-mode noise current (i.e., in-phase noise current) between the power terminals 11 and 21, and between the power terminals 12 and 22.

The windings 70a, 70b, 80a, and 80b form a differential mode inductor 141. The differential mode inductor 141 suppresses the flow of differential-mode ripple current (i.e., out-of-phase noise current) between the power terminals 11 and 21, and between the power terminals 12 and 22.

The windings 70a, 70b, 80a, 80b, and the smoothing capacitors 30 and 40 form a TT-type filter 120 (i.e., a filter circuit). The resistive element 90 is a first resistive element in the TT-type filter 120, connected in parallel with the winding 70b between the power terminals 11 and 21. The resistive element 91 is a second resistive element in the TT-type filter 120, connected in parallel with the winding 80b between the power terminals 12 and 22.

In this embodiment, the resistive elements 90 and 91 are made of electrical resistors with low temperature dependence.

In the following explanation, the common-mode inductor 140 and the differential mode inductor 141 will be collectively referred to as inductors 140 and 141.

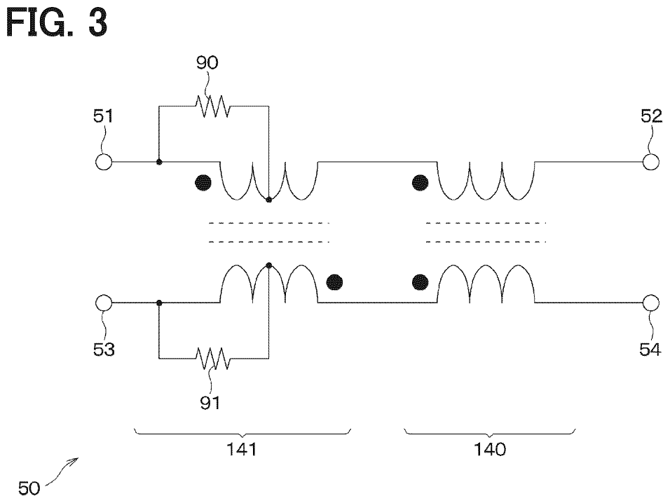

As shown in FIG. 3, the filter component 50 can be considered equivalent to a circuit in which inductors 140 and 141 are connected in series between the power terminals 11, 12 and the power terminals 21, 22, with resistive elements 90 and 91 connected in parallel to a part of the differential mode inductor 141.

In this embodiment, the resistive elements 90 and 91 each serve to suppress the occurrence of resonance in the TT-type filter 120, as will be described later.

As shown in FIG. 1, the driver 10, the smoothing capacitor 30, and the electric motor 10A together form a high-voltage apparatus 130. The driver 20, the smoothing capacitor 40, the electric motor 20A, and the filter component 50 together form a high-voltage apparatus 131. Terminals 51, 52, 53, and 54 shown in FIGS. 1 and 2 are the input and output terminals of the filter component 50, respectively.

The following describes an operation in the present embodiment.

First, the driver 10 supplies alternating current to the electric motor 10A through the switching operation of multiple switching elements, based on the output power supplied from the high-voltage battery 110. As a result, the electric motor 10A is driven by the alternating current supplied from the driver 10.

Additionally, the driver 20 supplies alternating current to the electric motor 20A through the switching operation of multiple switching elements, based on the output power supplied from the high-voltage battery 110. As a result, the electric motor 20A is driven by the alternating current supplied from the driver 20.

At this time, as indicated by arrows Ya and Yb in FIG. 1, common-mode noise currents (i.e., noise currents in the same phase) flow between the power terminals 11 and 21, and between the power terminals 12 and 22.

At this time, the windings 80a and 70a shown in FIG. 2 generate a magnetic flux that circulates through the magnetic circuit 100, based on the common-mode noise currents. The winding 80a generates a magnetic flux that reinforces the magnetic flux generated by the winding 70a, based on the common-mode noise currents.

In FIG. 2, an arrow B5 indicates the magnetic flux generated by the winding 80a, and an arrow B6 indicates the magnetic flux generated by the winding 70a.

The windings 80b and 70b generate magnetic fluxes that cancel each other out, based on the common-mode noise currents. In FIG. 2, an arrow B7 indicates the magnetic flux generated by the winding 70b, and an arrow B8 indicates the magnetic flux generated by the winding 80b.

As a result, inductance is generated in the windings 80a and 70a due to the magnetic flux circulating through the magnetic circuit 100. Accordingly, the windings 80a and 70a generate a counter electromotive force (back EMF) that cancels out the common-mode noise currents. Thus, the counter electromotive force (back EMF) generated in windings 80a and 70a suppresses the flow of common-mode noise currents through the windings 80a, 70a.

Additionally, due to the switching operation of the driver 10, differential mode ripple currents (i.e., out-of-phase noise currents) flow between the power terminals 11 and 21, and between the power terminals 12 and 22, as indicated by arrows Yc and Yd in FIG. 1.

The winding 80b generates a magnetic flux that enhances the magnetic flux produced by the winding 80a, based on the differential mode ripple current. The winding 70b generates a magnetic flux that enhances the magnetic flux produced by the winding 70a, based on the differential mode ripple current.

In FIG. 2, B1 indicates the magnetic flux generated by the winding 80a, and arrow B2 in FIG. 2 indicates the magnetic flux generated by the winding 70a. In FIG. 2, B4 indicates the magnetic flux generated by the winding 80b. In FIG. 2, B3 indicates the magnetic flux generated by the winding 70b.

Furthermore, the windings 80a and 70a generate magnetic fluxes in the circulating magnetic path 100 that cancel each other out based on the differential mode ripple current. As a result, the windings 80a, 80b, 70a, and 70b can reduce the magnetic energy based on the differential mode ripple current. Therefore, by reducing the energy of the differential mode ripple current, the flow of noise current through the windings 80a, 80b, 70a, and 70b is suppressed.

Additionally, the frequency of the differential mode ripple current generated due to the switching operation of the driver 10 may sometimes match the resonant frequency of the TT-type filter 120.

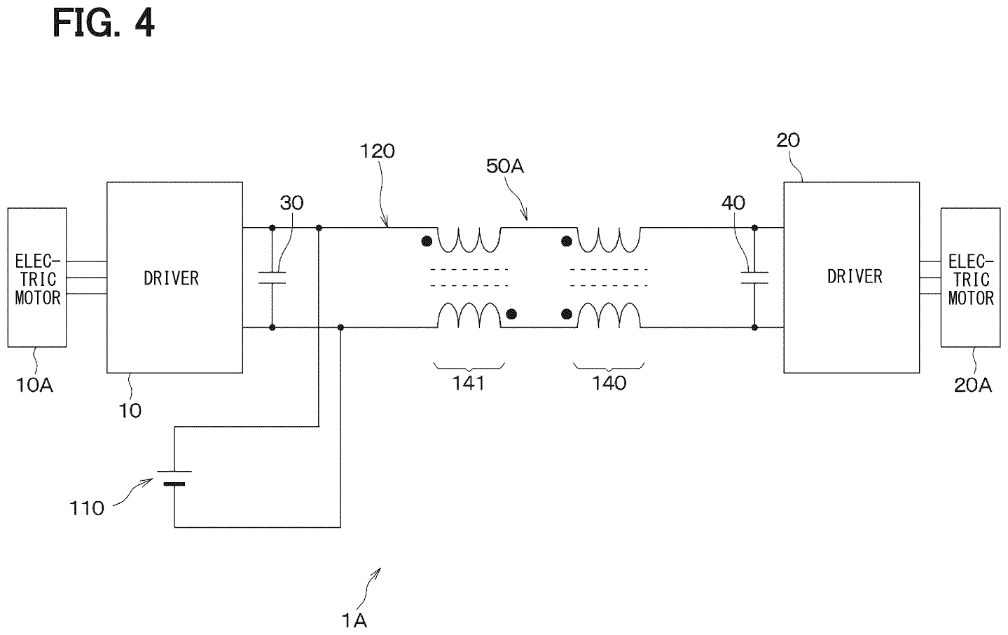

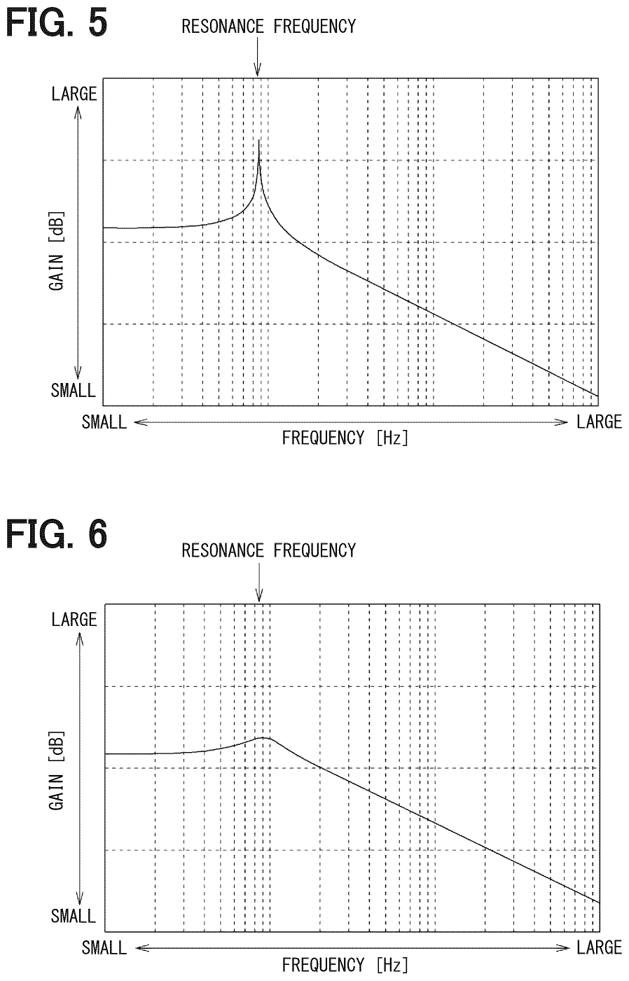

In this case, as shown in FIG. 4, if the filter component 50A do not include the resistive elements 90 and 91, resonance will occur in the TT-type filter 120 based on the aforementioned differential mode ripple current. In this case, as shown in FIG. 5, an excessive resonance current may flow through the smoothing capacitor 40, potentially causing a fault in the smoothing capacitor 40.

FIG. 5 shows the transfer characteristics of the high-voltage system 1A equipped with the filter component 50A that do not include resistive elements 90 and 91. As can be seen from FIG. 5, there is a large peak in the gain at the resonant frequency.

The transfer characteristics in FIG. 5 are plotted with the differential mode ripple current generated due to the switching operation of the drive device 10 as In and the ripple current flowing through the smoothing capacitor 40 as Iout. The vertical axis represents the gain, while the horizontal axis represents the frequency. Gain is the ratio of Iout to In. That is, the gain is Iout divided by In and is expressed in dB.

In contrast, in the present embodiment, the resistive element 90 is connected in parallel with the winding 70b in the TT-type filter 120. The resistive element 91 is connected in parallel with the winding 80b in the TT-type filter 120.

Therefore, a portion of the differential mode ripple current flows through the resistive elements 90 and 91. Therefore, in the resistive elements 90 and 91, a portion of the differential mode ripple current is converted into Joule heat, thereby reducing the energy of the differential mode ripple current. Thus, by preventing resonance from occurring in the TT-type filter 120, it is possible to effectively suppress the ripple current flowing through the smoothing capacitor 40.

FIG. 6 illustrates the transmission characteristics of the high-voltage system in the present embodiment. As can be seen from FIG. 6, the gain at the resonant frequency shows that the peak is effectively attenuated compared to FIG. 5.

According to the embodiment described above, in the high-voltage system 1, the drivers 10 and 20 are connected in parallel to the high-voltage battery 110, and they convert the output power of the high-voltage battery 110 into AC power through switching operation.

The smoothing capacitor 30 is connected between the power terminals 11 and 12 of the driver 10 to stabilize the power supply voltage output from the high-voltage battery 110 to the driver 10.

The smoothing capacitor 40 is connected between the power terminals 21 and 22 of the driver 10 to stabilize the power supply voltage output from the high-voltage battery 110 to the driver 10.

The magnetic core 60 includes the outer core 61 and the short-circuit core 62. The outer core 61 is formed to enclose the two empty spaces 61e to form the circulating magnetic path 100 through which the magnetic flux circulates. The short-circuit core 62 magnetically connects two parts 101 and 102 of the outer core 61 to form the short-circuit magnetic path 103 that allows the magnetic flux to pass through these two parts 101 and 102. The short-circuit core 62 is positioned between the two empty spaces 61e.

The winding 70a is wound around the left core 61a of the magnetic core 60, allowing the magnetic flux to pass through the circulating magnetic path 100. The winding 70b is wound around the short-circuit core 62 of the magnetic core 60 to allow the magnetic flux to pass through both the circulating magnetic path 100 and the short-circuit magnetic path 103.

The winding 80a is wound around the right core 61b of the magnetic core 60 to allow the magnetic flux to pass through the circulating magnetic path 100. The winding 80b is wound around the short-circuit core 62 of the magnetic core 60 to allow the magnetic flux to pass through both the circulating magnetic path 100 and the short-circuit magnetic path 103. The windings 70a and 70b are connected in series between the power terminals 11 and 21, while the windings 80a and 80b are connected in series between the power terminals 12 and 22.

The windings 80a and 70a are wound in such a way that they form a common-mode inductor 140. This configuration suppresses common-mode (i.e., in-phase) noise current flowing between the power terminals 11 and 21 and between the power terminals 21 and 22.

The windings 80a, 80b, 70a, and 70b are wound in such a manner that they form a differential-mode inductor. This winding configuration allows the inductors to effectively suppress differential-mode noise currents. The differential-mode inductor suppresses differential-mode (i.e., out-of-phase) ripple currents flowing between the power terminals 11 and 21 and between the power terminals 12 and 22.

The windings 80a, 80b, 70a, 70b, and the smoothing capacitors 30 and 40 together form the TT-type filter 120. This configuration helps in filtering out unwanted noise and ripple currents.

The resistive element 90 is connected in parallel with the winding 70b within the TT-type filter 120, and converts a portion of the differential-mode current into Joule heat. In addition, the resistive element 91 is connected in parallel to the winding 80b in the TT-type filter 120, and converts a part of the differential mode current into Joule heat. This makes it possible to reduce the current in the differential mode.

Thus, the filter component 50 is designed to suppress resonance in the TT-type filter 120, which has the smoothing capacitors 30, 40 and the windings 70a, 70b, 80a, and 80b. This is achieved by incorporating the resistive elements 90 and 91, which convert a portion of the differential-mode current into Joule heat, thereby damping potential resonances.

Furthermore, the filter component 50A, which lacks the resistive elements 90 and 91, is prone to large currents flowing due to resonance, resulting in heat generation. For this reason, the filter component 50A needs to be enlarged in size in order to ensure heat dissipation.

In contrast, in the present embodiment, the filter component 50 is equipped with the resistive elements 90 and 91, which suppress the occurrence of resonance. As a result, the heat generation in the filter component 50 is suppressed that allows the potential miniaturization of the filter component 50.

In the present embodiment, the resistive elements 90 and 91 are connected in parallel with a part of the differential-mode inductor 141 between the power terminals 11, 12 and the power terminals 21, 22. Therefore, the resistive elements 90 and 91 can be prevented from affecting the operation of the common-mode inductor 140.

The following describes an example of the filter component 50 in the present embodiment.

The ripple current Iout flowing into the smoothing capacitor 40 varies in its inflow amount based on the transfer characteristics from the high-voltage apparatus 130 to the high-voltage apparatus 131. Here, the capacitance of the smoothing capacitor 30 is sufficiently larger than the capacitance of the smoothing capacitor 40. The resonant frequency of the TT-type filter 120 is determined by the inductance of the differential-mode inductor 141 in the filter component 50 and the capacitance of the smoothing capacitor 40.

The transfer characteristics are adjusted so that the resonant frequency falls on the lower frequency side (for example, between 1 kHz and 100 kHz) by tuning the inductance of the differential-mode inductor 141 and the capacitance of the smoothing capacitor 40. This is done to suppress conducted emission noise on the high-frequency side, for example, above 150 kHz, in the high-voltage apparatus 131.

Moreover, the resistance values of the resistive elements 90, 91 are set so as to reduce the current peak at the resonant frequency. Specifically, it is possible to set the resistance values of the resistive elements 90 and 91 such that their impedance is approximately equal to the impedance of the differential-mode inductor 141 at the resonant frequency. This effectively reduces the current peak at the resonant frequency.

### Second Embodiment

In the above first embodiment, an example had been described where the resistive element 90 is arranged in parallel with the winding 70b between the power terminals 11 and 21, and the resistor element 91 is arranged in parallel with the winding 80b between the power terminals 12 and 22.

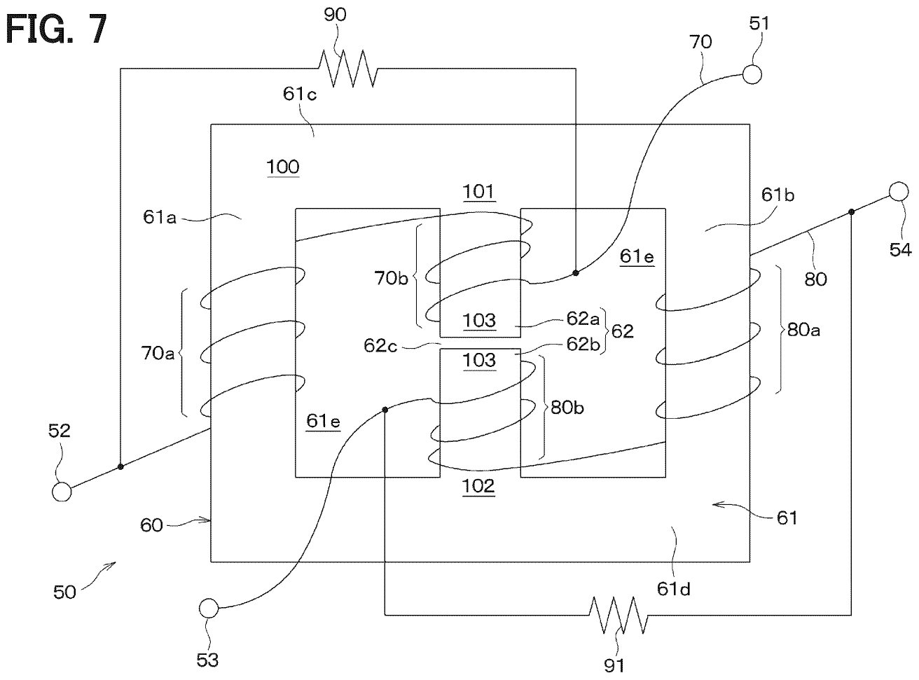

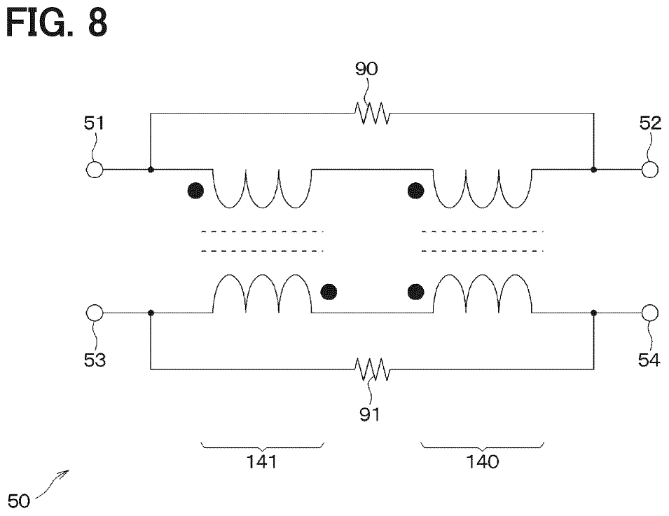

However, this is not limited to the first embodiment. In the second embodiment, as shown in FIGS. 7 and 8, the resistive elements 90 and 91 may be arranged accordingly.

In this embodiment, the resistive element 90 is arranged in parallel across the windings 70a and 70b between the power terminals 11 and 21 in the TT-type filter 120. The resistive element 91 is arranged in parallel across the windings 80a and 80b between the power terminals 12 and 22 in the TT-type filter 120. The power terminals 11, 21, 12, and 22 are omitted from FIG. 7.

The equivalent circuit of the filter component 50 shown in FIG. 7 is illustrated in FIG. 8. The filter component 50 can be considered equivalent to a circuit in which the inductors 140 and 141 are connected in series between the power terminals 11 and 12, and the power terminals 21 and 22, with the resistor elements 90 and 91 connected in parallel across the inductors 140 and 141.

Therefore, a portion of the differential mode current flowing through the filter component 50 is converted into Joule heat by the resistive elements 90 and 91, thereby reducing the differential mode current.

In the filter component 50 in the present embodiment, since the other configurations are the same as those of the filter component 50 of the first embodiment except for the arrangement of the resistor elements 90 and 91, the description of the other configurations will be omitted.

According to the present embodiment described above, the resistor element 90 is arranged in parallel across the windings 70a and 70b between the power terminals 11 and 21 in the TT-type filter 120. The resistor element 91 is arranged in parallel across the windings 80a and 80b between the power terminals 22 and 22 in the TT-type filter 120. Therefore, the resistor elements 90 and 91 convert a portion of the differential mode current into Joule heat, thereby reducing the differential mode current. For this reason, it is possible to suppress the occurrence of resonance in the TT-type filter 120.

### Third Embodiment

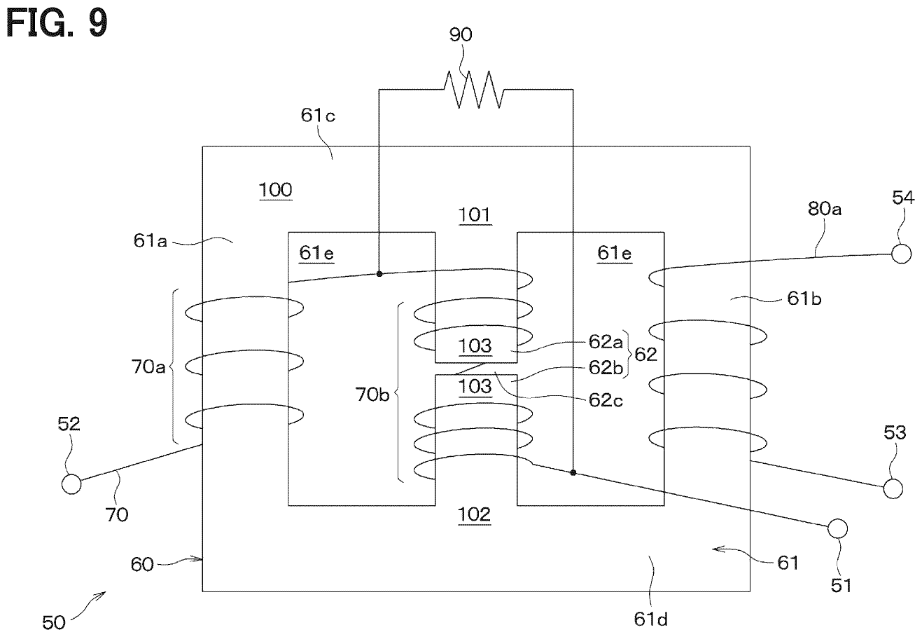

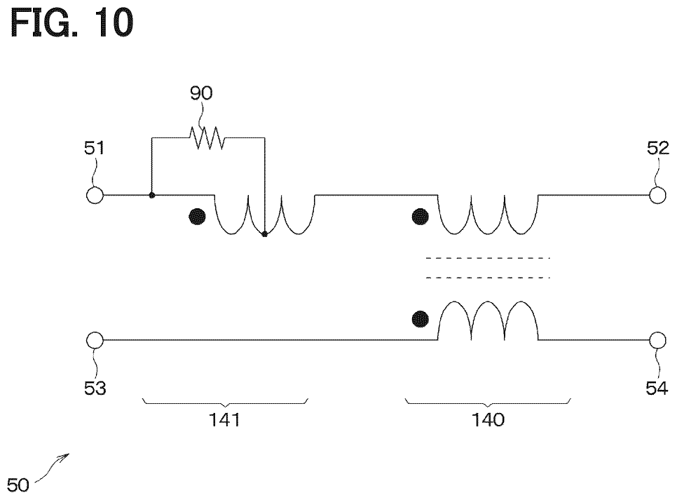

In the first embodiment, an example is described in which the windings 80a and 80b are connected in series between the power terminals 12 and 22. However, instead of the above example, the third embodiment will be described with reference to FIGS. 9 and 10, in which only the winding 80a of the windings 80a and 80b is connected between the power terminals 12 and 22.

FIG. 9 shows the configuration of the filter component 50 in the present embodiment. In the filter component 50 in the present embodiment, the winding 80b and the resistive element 91 are omitted from the first embodiment. For this reason, the winding 80a is connected between the power terminals 12 and 22. The winding 70b in the present embodiment is wound over the upper core 62a and the lower core 62b of the short-circuit core 62. In the present embodiment, components other than the winding 80b, the resistive element 91, and the winding 70b (for example, the winding 80a and the magnetic core 60) are the same as in the first embodiment.

In the present embodiment constructed as described above, as shown in FIG. 10, the windings 70a and 80a form the common-mode inductor 140. The windings 70a, 70b, and 80a form the differential mode inductor 141.

According to the present embodiment described above, the windings 70a and 80a form the common-mode inductor 140, and the windings 70a, 70b, and 80a form the differential mode inductor 141, with the windings 70 and 80a wound accordingly.

In the TT-type filter 120, the resistive element 90 is connected in parallel with the winding 70b between the power terminals 11 and 21. FIG. 10 shows the equivalent circuit of the filter component 50 illustrated in FIG. 9. The filter component 50 can be considered equivalent to a circuit in which the inductors 141 and 140 are connected in series between the power terminals 11, 12 and the power terminals 21, 22, and the resistive element 90 is connected in parallel to a part of the differential mode inductor 141. Therefore, a part of the differential mode current flowing through the filter component 50 is converted to Joule heat by the resistive element 90, thereby reducing the differential mode current. As a result, the resistive element 90 can suppress the occurrence of resonance in the TT-type filter 120.

### Fourth Embodiment

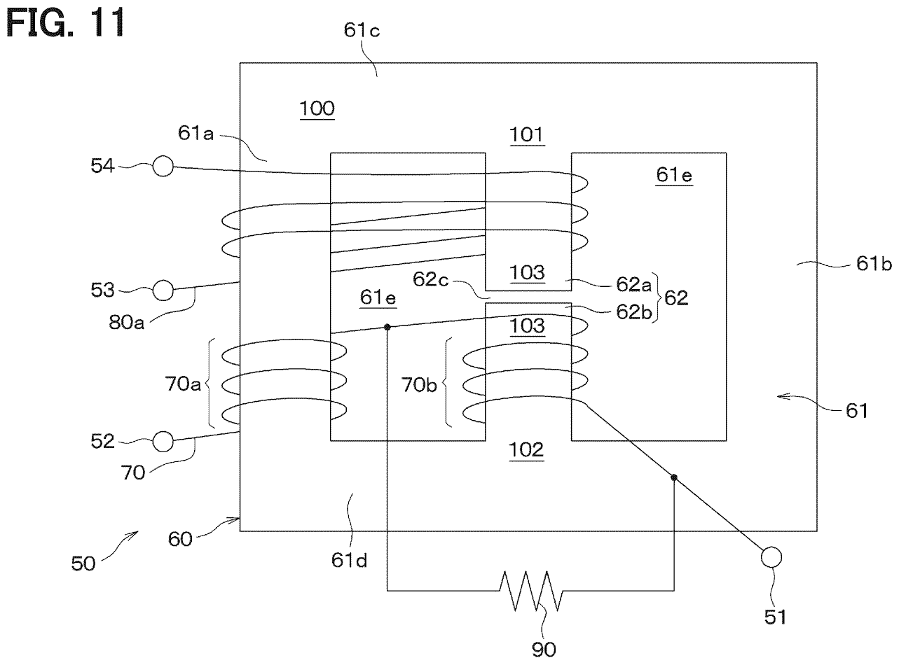

In the above third embodiment, an example in which the winding 80a is wound around the right core 61b is described. However, instead of the above example, the fourth embodiment, in which the winding 80a is wound so as to encircle both the left core 61a and the upper core 62a, will be described with reference to FIG. 11.

In the present embodiment and the above third embodiment, only the arrangement of the winding 80a differs, and the other configurations are the same as those in the above third embodiment.

Therefore, similarly to the third embodiment, the windings 70a and 80a form the common-mode inductor 140. The windings 70a, 70b, and 80a form the differential mode inductor 141.

According to the present embodiment described above, the resistive element 90 is connected in parallel with the winding 70b between the power terminals 11 and 21 in the TT-type filter 120. Therefore, similar to the above third embodiment, the resistive element 90 can reduce the differential mode current flowing through the TT-type filter 120. Thus, the resistive element 90 can prevent resonance from occurring in the TT-type filter 120.

### Fifth Embodiment

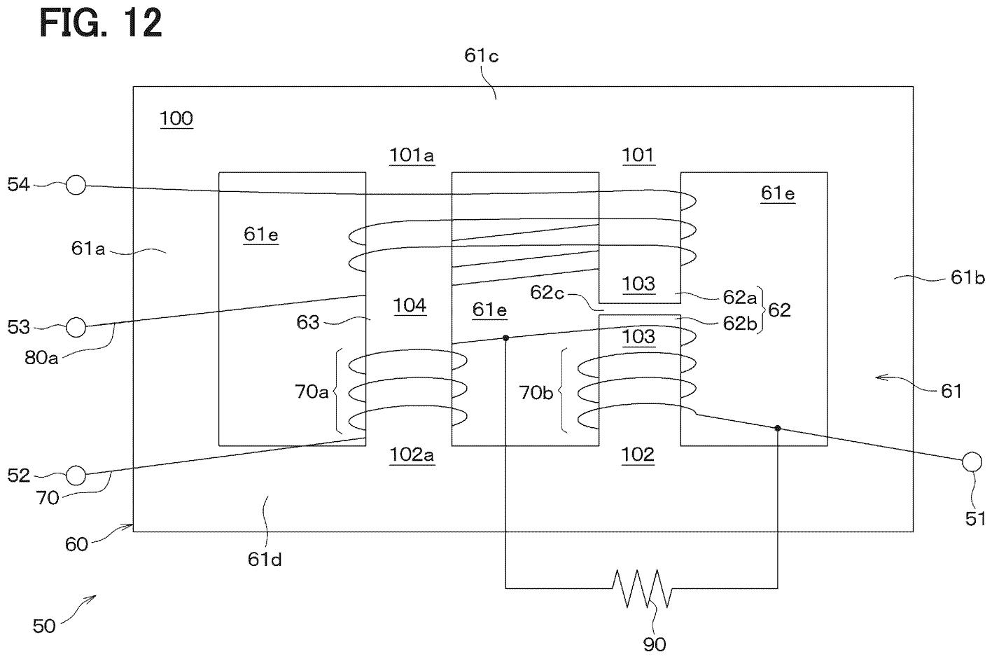

In the above fourth embodiment, an example where the winding 70a is wound around the right core 61b is described. However, instead of the above example, the present embodiment, in which the winding 70a is wound around the short-circuit core 63, will be described with reference to FIG. 12.

In the present embodiment and the above fourth embodiment, the arrangement of the winding 70a, the arrangement of the winding 80a, and the magnetic core 60 differ. In the magnetic core 60 according to the present embodiment, the short-circuit core 63 is added to the magnetic core 60 in the above fourth embodiment.

The short-circuit core 63 connects the part 101a of the upper core 61c and the part 102a of the lower core 61d, forming a short-circuit magnetic path 104 through which the magnetic flux passes. The short-circuit core 63, along with the short-circuit core 62, forms three empty spaces 61e inside the outer core 61.

The winding 70a is wound around the short-circuit core 63 as described above. The winding 80a is wound so as to circle around the short-circuit core 63 and the upper core 62a together.

In the present embodiment and the above fourth embodiment, only the arrangement of the winding 80a, the arrangement of the winding 70a, and the short-circuit core 63 differ; other configurations are the same as in the above fourth embodiment.

Therefore, similar to the above fourth embodiment, the windings 70a and 80a form the common-mode inductor 140. The windings 70a, 70b, and 80a form the differential mode inductor 141.

According to the present embodiment described above, the resistive element 90 is connected in parallel with the winding 70b between the power terminals 11 and 21 in the TT-type filter 120. Therefore, similar to the above fourth embodiment, the resistive element 90 can reduce the differential mode current flowing through the TT-type filter 120. Thus, the resistive element 90 can prevent resonance from occurring in the TT-type filter 120.

### Sixth Embodiment

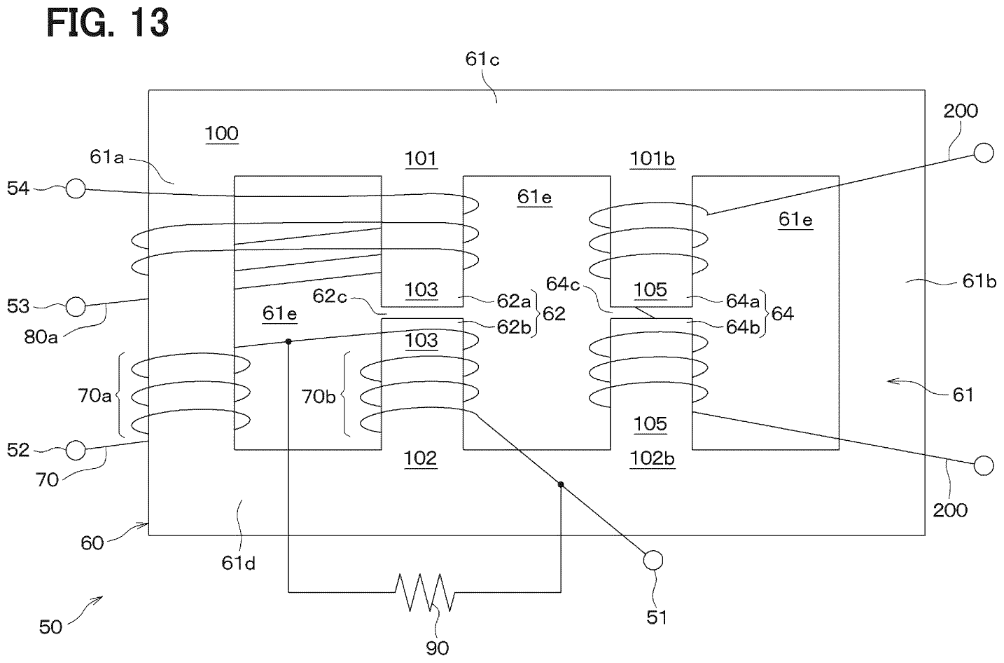

In a sixth embodiment, an example in which a winding 200, which is included in a differential mode inductor, is added to the filter component 50 of the fourth embodiment will be described with reference to FIG. 13. The winding 200 according to the present embodiment is wound around the upper core 64a and the lower core 64b of the short-circuit core 64. The short-circuit core 64 connects the part 101b of the upper core 61c and the part 102b of the lower core 61d, forming a short-circuit magnetic path 105 through which the magnetic flux passes. The short-circuit core 64, along with the short-circuit core 63, forms three empty spaces 61e inside the outer core 61. The short-circuit core 64 comprises the upper core 64a and the lower core 64b.

The upper core 64a is formed so as to protrude from the upper core 61c towards the lower core 61d. The lower core 62b is formed so as to protrude from the lower core 61d towards the upper core 61c. A gap 64c is provided between the upper core 64a and the lower core 64b. The gap 64c may also be referred to as an empty space or an empty gap.

In the present embodiment and the above fourth embodiment, the only differences are the winding 200 and the short-circuit core 64; the other configurations are the same as those in the above fourth embodiment.

Therefore, similar to the above fourth embodiment, the windings 70a and 80a form the common-mode inductor 140. The windings 70a, 70b, and 80a form the differential mode inductor 141. The winding 200 forms an inductance independent of the differential mode inductor 141.

According to the present embodiment described above, the resistive element 90 is connected in parallel with the winding 70b between the power terminals 11 and 21 in the TT-type filter 120. Therefore, similar to the above fourth embodiment, the resistive element 90 can reduce the differential mode current flowing through the TT-type filter 120. Thus, the resistive element 90 can prevent resonance from occurring in the TT-type filter 120.

### Seventh Embodiment

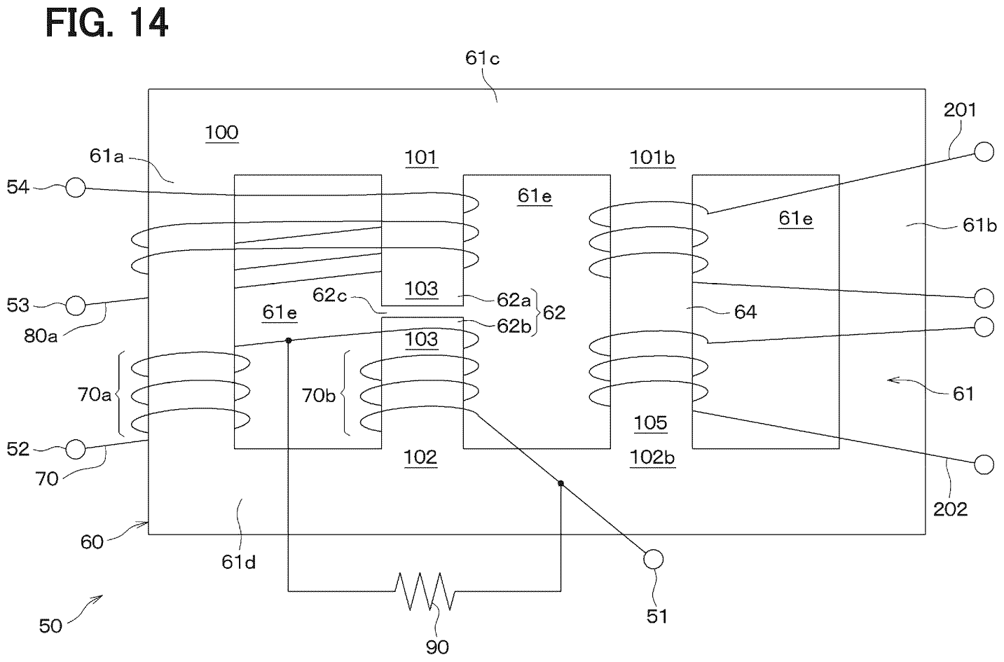

In the above sixth embodiment, an example is described in which the winding 200 that is included in the differential mode inductor is wound around the upper core 64a and the lower core 64b of the short-circuit core 64. However, instead of the above example, a seventh embodiment, in which the windings 201 and 202 that are included in the transformer are wound around the short-circuit core 64, will be described with reference to FIG. 14. In the present embodiment, the winding 201 and winding 202 are each wound around the short-circuit core 64. The short-circuit core 64 does not have the gap 64c.

In the present embodiment and the above sixth embodiment, the only differences are the windings 201 and 202 replacing the winding 200, and the short-circuit core 64; the other configurations remain the same.

According to the present embodiment described above, the resistive element 90 is connected in parallel with the winding 70b between the power terminals 11 and 21 in the TT-type filter 120. Therefore, similar to the above sixth embodiment, the resistive element 90 can reduce the differential mode current flowing through the TT-type filter 120. Thus, the resistive element 90 can prevent resonance from occurring in the TT-type filter 120.

### Eighth Embodiment

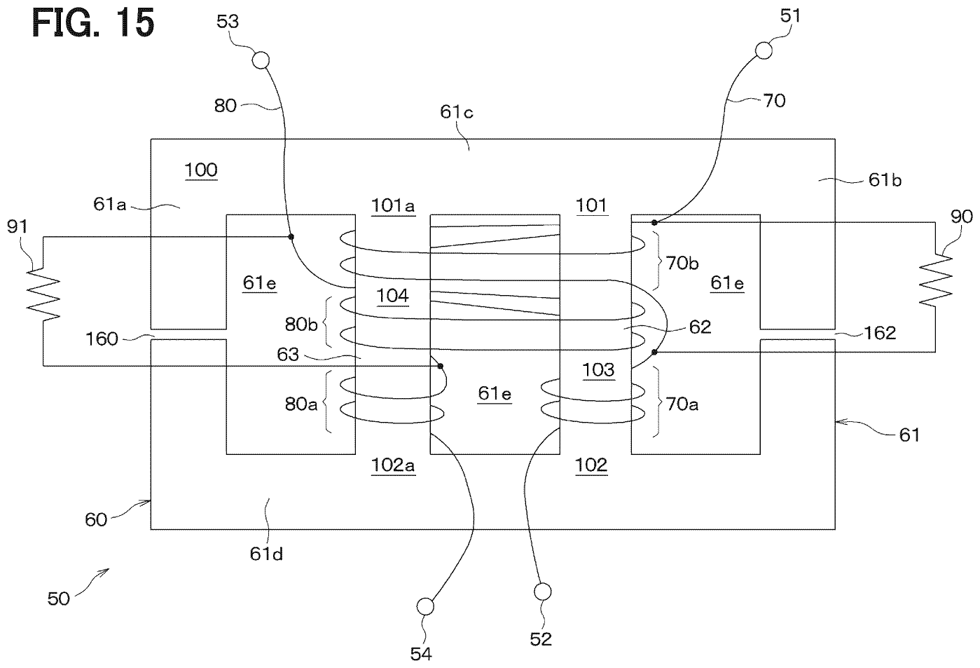

In the above first embodiment, an example in which one short-circuit core 62 is provided in the magnetic core 60 is described. However, instead of the above example, an eighth embodiment in which two short-circuit cores 62, 63 are provided in the magnetic core 60 will be described with reference to FIG. 15.

In the present embodiment and the above first embodiment, the magnetic core 60, and windings 70a, 70b, 80a, and 80b differ.

The short-circuit core 63 in the present embodiment connects the part 101a of the upper core 61c and the part 102a of the lower core 61d, forming a short-circuit magnetic path 104 through which the magnetic flux passes. The short-circuit core 64, along with the short-circuit core 62, forms three empty spaces 61e inside the outer core 61.

The winding 70a is wound around the short-circuit core 62, and the winding 70b is wound so as to encircle both of the short-circuit cores 62 and 63.

The winding 80a is wound around the short-circuit core 63, and the winding 80b is wound so as to encircle both of the short-circuit cores 62 and 63.

Furthermore, in the magnetic core 60 in the present embodiment, a gap 160 is provided in the left core 61a, and a gap 161 is provided in the right core 61b. The short-circuit core 62 in FIG. 15 does not have the gap 62c. The gap 160 may also be referred to as an empty space or an empty gap.

According to the present embodiment described above, the resistive element 90 is connected in parallel with the winding 70b between the power terminals 11 and 21 in the TT-type filter 120. In the TT-type filter 120, the resistive element 91 is connected in parallel with the winding 80b between the power terminals 12 and 22. Therefore, similar to the above first embodiment, the resistive element 90 can reduce the differential mode current flowing through the TT-type filter 120. Thus, the resistive elements 90 and 91 can prevent resonance from occurring in the TT-type filter 120.

### Ninth Embodiment

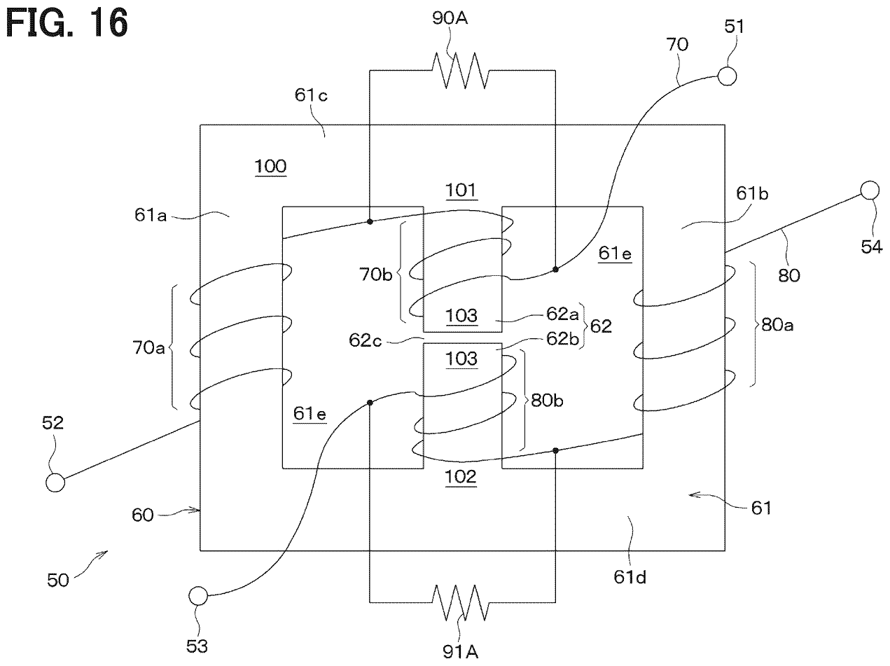

In the above first to eighth embodiments, examples are described in which the resistive elements 90 and 91, having low temperature dependence in their electrical resistance values, are used as resistive elements. However, instead of the above examples, a ninth embodiment will be described with reference to FIG. 16, in which thermosensitive resistors with high temperature dependence in their electrical resistance values are used as resistive elements 90A and 91A (i.e., the first resistive element and the second resistive element).

The thermal resistor is, for example, a positive temperature coefficient (PTC) thermal resistor having a positive temperature coefficient in electrical resistance. When PTCs are used as the resistive elements 90A and 91A, the electrical resistance values of the resistive elements 90A and 91A increase as they generate heat and their temperatures rise. Therefore, as the temperature of the resistive elements 90A and 91A increases, it is expected that by limiting the current flowing through the resistive elements 90A and 91A, overheating of these elements can be suppressed, thereby preventing damage to the resistive elements 90A and 91A.

Additionally, the resistive elements 90A and 91A may be formed by combining a general resistor, which has low temperature dependence in its electrical resistance value, with a thermosensitive resistor. For example, if it is difficult to fine-tune the electrical resistance value using only the thermosensitive resistor, it is expected that combining a general resistor with the thermosensitive resistor can adjust the total electrical resistance value to the desired level.

### Other Embodiments

In each of the above first to ninth embodiments, an example is described in which the electric device is the driver 20 that drives the electric motor 20A. However, this is not limited to electric motors; another electric device may also be the driver 20 that drives other components such as electric heaters.

In each of the first, second, eighth, and ninth embodiments, an example is described in which the windings 70a and 70b are connected in series between the power terminals 11 and 21, and the windings 80a and 80b are connected in series between the power terminals 12 and 22.

Alternatively, the windings 80a and 80b may be connected in series between the power terminals 11 and 21, and the windings 70a and 70b may be connected in series between the power terminals 12 and 22. In this case, the negative electrode 112 serves as the first electrode, and the positive electrode 111 serves as the second electrode. The power terminal 12 serves as the first power terminal, and the power terminal 11 serves as the second power terminal. The power terminal 22 serves as the third power terminal, and the power terminal 21 serves as the fourth power terminal.

In this case, the resistive element 91 is connected in parallel with at least one of the windings 80a or 80b, and the resistive element 90 is connected in parallel with at least one of the windings 70a or 70b.

In each of the third, fourth, fifth, sixth, and seventh embodiments, an example is described in which the windings 70a and 70b are connected in series between the power terminals 11 and 21, and the winding 80a is connected between the power terminals 12 and 22.

Alternatively, the winding 80a may be connected between the power terminals 11 and 21, and the windings 70a and 70b may be connected between the power terminals 12 and 22. In this case, the negative electrode 112 serves as the first electrode, and the positive electrode 111 serves as the second electrode. The power terminal 12 serves as the first power terminal, and the power terminal 11 serves as the second power terminal. The power terminal 22 serves as the third power terminal, and the power terminal 21 serves as the fourth power terminal.

In this case, the resistive element 90 is connected in parallel with the winding 70b.

In each of the above first to ninth embodiments, the high voltage system 1 is applied to an electric vehicle. Alternatively, the high voltage system 1 may be applied to various devices other than electric vehicles.

In each of the first and eighth embodiments, an example is described in which the resistive element 90 is connected in parallel with the winding 70b between the power terminals 11 and 21. Alternatively, the following configurations (a) and (b) may be used: (a) the resistor element 90 may be connected in parallel with the winding 70a between the power terminals 11 and 21; and (b) the resistive element 90 may be connected in parallel with the winding 70b between the power terminals 11 and 21, and another resistive element different from the resistive element 90 may be connected in parallel with the winding 70a between the power terminals 11 and 21.

Similarly, in the ninth embodiment, the following configurations (c), (d), and (e) may be used: (c) the resistive element 90A may be connected in parallel with the winding 70a between the power terminals 11 and 21; (d) the resistive element 90A may be connected in parallel with the winding 70b between the power terminals 11 and 21, and another resistive element different from the resistive element 90 may be connected in parallel with the winding 70a between power terminals 11 and 21; and (e) the resistive element 90A may be connected in parallel across the windings 70a and 70b between the power terminals 11 and 21.

In each of the first and eighth embodiments, an example is described in which the resistive element 91 is connected in parallel with the winding 80b between the power terminals 12 and 22. Alternatively, the following configurations (f) and (g) may be used: (f) the resistive element 91 may be connected in parallel with the winding 80a between the power terminals 12 and 22; and (g) the resistive element 91 may be connected in parallel with the winding 80b between the power terminals 12 and 22, and another resistor element different from the resistive element 91 may be connected in parallel with the winding 80a between the power terminals 12 and 22.

Similarly, in the ninth embodiment, the following configurations (h), (i), and (j) may be used: (h) the resistive element 91A may be connected in parallel with the winding 80a between the power terminals 12 and 22; (i) the resistive element 91A may be connected in parallel with the winding 80b between the power terminals 12 and 22, and another resistive element different from the resistive element 91A may be connected in parallel with the winding 80a between the power terminals 12 and 22; and (j) the resistive element 91A may be connected in parallel across the windings 80a and 80b between the power terminals 12 and 22.

In each of the third, fourth, fifth, sixth, and seventh embodiments, an example is described in which the resistive element 90 is connected in parallel with the winding 70b between the power terminals 11 and 21. Alternatively, the following configurations (k), (l), (m), and (n) may be used: (k) the resistive element 90 may be connected in parallel with the winding 70a between the power terminals 11 and 21; (l) the resistive element 90 may be connected in parallel with the winding 70b between the power terminals 11 and 21, and another resistive element different from the resistive element 90 may be connected in parallel with the winding 70a between the power terminals 11 and 21; (m) the resistive element 90 may be connected in parallel across the windings 70a and 70b between the power terminals 11 and 21; and (n) the resistive element 90 may be connected in parallel with the winding 80a between the power terminals 12 and 22.

In the ninth embodiment, an example is described in which the PTC resistive element 90A is used in place of the resistive element 90, and the PTC resistive element 91A us used in place of the resistive element 91.

Similarly, in the second to eighth embodiments, the resistive element 90 may be replaced with the resistive element 90A that is a PTC resistor. Additionally, in the second and eighth embodiments, the PTC resistive element 91A may be used in place of the resistive element 91.

The present disclosure is not limited to the embodiments described above but may be appropriately modified. The above-described embodiments are not independent of each other, and can be appropriately combined except when the combination is obviously impossible. In each of the above-described embodiments, individual elements or features of a particular embodiment are not necessarily essential unless it is specifically stated that the elements or the features are essential, or unless the elements or the features are obviously essential in principle. A quantity, a value, an amount, a range, or the like, if specified in the above-described example embodiments, is not necessarily limited to the specific value, amount, range, or the like unless it is specifically stated that the value, amount, range, or the like is necessarily the specific value, amount, range, or the like, or unless the value, amount, range, or the like is obviously necessary to be the specific value, amount, range, or the like in principle. In each of the embodiments, when referring to the shape, positional relationship, and the like of the constituent elements and the like, the shape, positional relationship, and the like are not limited unless otherwise specified or limited to a specific shape, positional relationship, and the like in principle.

What is claimed is:

1. A filter component configured to be adapted to an electrical system having a first smoothing capacitor, a second smoothing capacitor, a first electric apparatus, and a second electric apparatus, each of the first electric apparatus and the second electric apparatus being connected in parallel to a battery and configured to be operated by an output power of the battery, the first smoothing capacitor configured to stabilize a power supply voltage supplied from the battery to the first electric apparatus, the second smoothing capacitor configured to stabilize the power supply voltage supplied from the battery to the second electric apparatus, the filter component comprising:
a magnetic core including
an outer core surrounding two empty spaces of the magnetic core and having a circulating magnetic circuit configured to circulate a magnetic flux, and
a short-circuit core located between the two empty spaces and having a short-circuit magnetic circuit configured to allow a magnetic flux to flow through a location between two parts of the outer core;
a first winding, a second winding, a third winding, and a fourth winding, which are wound around the magnetic core to generate the magnetic flux that flows through the circulating magnetic circuit and the magnetic flux that flows through the short-circuit magnetic circuit;
a first resistive element; and
a second resistive element, wherein
the battery has two electrodes being a first electrode and a second electrode, respectively,
the first electric apparatus has a power terminal being a first power terminal connected to the first electrode of the battery, and has another power terminal being a second power terminal connected to the second electrode of the battery,
the second electric apparatus has a power terminal being a third power terminal connected to the first electrode of the battery, and has another power terminal being a fourth power terminal connected to the second electrode of the battery,
the first winding and the second winding are connected in series between the first power terminal and the third power terminal,
the third winding and the fourth winding are connected in series between the second power terminal and the fourth power terminal,
the first winding and the third winding form a common-mode inductor configured to suppress a common-mode noise current flowing between the first power terminal and the third power terminal as well as between the second power terminal and the fourth power terminal,
the first winding, the second winding, the third winding, and the fourth winding form a differential-mode inductor configured to suppress a differential-mode noise current flowing between the first power terminal and the third power terminal as well as between the second power terminal and the fourth power terminal,
the first winding, the second winding, the third winding, the fourth winding, the first smoothing capacitor, and the second smoothing capacitor form a filter circuit,
the first resistive element is connected in parallel across at least one of the first winding, the second winding, the third winding, or the fourth winding in the filter circuit, and is configured to suppress a resonance in the filter circuit,
the second resistive element is configured to suppress the resonance in the filter circuit,
the first resistive element is connected in parallel across the first winding and the second winding between the first power terminal and the third power terminal, and
the second resistive element is connected in parallel across the third winding and the fourth winding between the second power terminal and the fourth power terminal.

2. The filter component according to claim 1, wherein
the first resistive element is connected in parallel to the second winding between the first power terminal and the third power terminal, and
the second resistive element is connected in parallel to the fourth winding between the second power terminal and the fourth power terminal.

3. The filter component according to claim 1, wherein
the first winding is wound around the outer core,
the second winding is wound around the short-circuit core,
the third winding is wound around the outer core, and
the fourth winding is wound around the short-circuit core.

4. The filter component according to claim 1, wherein
a capacitance of the first smoothing capacitor is larger than a capacitance of the second smoothing capacitor, and
a frequency of the resonance in the filter circuit is set based on the capacitance of the second smoothing capacitor and an inductance of the differential-mode inductor.

5. A filter component configured to be adapted to an electrical system having a first smoothing capacitor, a second smoothing capacitor, a first electric apparatus, and a second electric apparatus, each of the first electric apparatus and the second electric apparatus being connected in parallel to a battery and configured to be operated by an output power of the battery, the first smoothing capacitor configured to stabilize a power supply voltage supplied from the battery to the first electric apparatus, the second smoothing capacitor configured to stabilize the power supply voltage supplied from the battery to the second electric apparatus, the filter component comprising:
a magnetic core including
an outer core surrounding two empty spaces of the magnetic core and having a circulating magnetic circuit configured to circulate a magnetic flux, and
a short-circuit core located between the two empty spaces and having a short-circuit magnetic circuit configured to allow a magnetic flux to flow through a location between two parts of the outer core;
a first winding, a second winding, a third winding, and a fourth winding, which are wound around the magnetic core to generate the magnetic flux that flows through the circulating magnetic circuit and the magnetic flux that flows through the short-circuit magnetic circuit; and
a resistive element, wherein
the battery has two electrodes being a first electrode and a second electrode, respectively,
the first electric apparatus has a power terminal being a first power terminal connected to the first electrode of the battery, and has another power terminal being a second power terminal connected to the second electrode of the battery,
the second electric apparatus has a power terminal being a third power terminal connected to the first electrode of the battery, and has another power terminal being a fourth power terminal connected to the second electrode of the battery,
the first winding and the second winding are connected in series between the first power terminal and the third power terminal,
the third winding and the fourth winding are connected in series between the second power terminal and the fourth power terminal,
the first winding and the third winding form in a common-mode inductor configured to suppress a common-mode noise current flowing between the first power terminal and the third power terminal as well as between the second power terminal and the fourth power terminal,
the first winding, the second winding, the third winding, and the fourth winding form a differential-mode inductor configured to suppress a differential-mode noise current flowing between the first power terminal and the third power terminal as well as between the second power terminal and the fourth power terminal,
the first winding, the second winding, the third winding, the fourth winding, the first smoothing capacitor, and the second smoothing capacitor form a filter circuit,
the resistive element is connected in parallel across at least one of the first winding, the second winding, the third winding, or the fourth winding in the filter circuit, and is configured to suppress a resonance in the filter circuit,
the first smoothing capacitor and the second smoothing capacitor are included in the filter component,
a capacitance of the first smoothing capacitor is larger than a capacitance of the second smoothing capacitor, and
a frequency of the resonance in the filter circuit is set based on the capacitance of the second smoothing capacitor and an inductance of the differential-mode inductor.

6. A filter component configured to be adapted to an electrical system having a first smoothing capacitor, a second smoothing capacitor, a first electric apparatus, and a second electric apparatus, each of the first electric apparatus and the second electric apparatus being connected in parallel to a battery and configured to be operated by an output power of the battery, the first smoothing capacitor configured to stabilize a power supply voltage supplied from the battery to the first electric apparatus, the second smoothing capacitor configured to stabilize the power supply voltage supplied from the battery to the second electric apparatus, the filter component comprising:
a magnetic core including
an outer core surrounding two empty spaces of the magnetic core and having a circulating magnetic circuit configured to circulate a magnetic flux, and
a short-circuit core located between the two empty spaces and having a short-circuit magnetic circuit configured to enable a magnetic flux to flow through a location between two parts of the outer core;
a first winding, a second winding, and a third winding, which are wound around the magnetic core to generate the magnetic flux that flows through the circulating magnetic circuit and the magnetic flux that flows through the short-circuit magnetic circuit; and
a resistive element, wherein
the battery has two electrodes being a first electrode and a second electrode, respectively,
the first electric apparatus has a power terminal being a first power terminal connected to the first electrode of the battery, and has another power terminal being a second power terminal connected to the second electrode of the battery,
the second electric apparatus has a power terminal being a third power terminal connected to the first electrode of the battery, and has another power terminal being a fourth power terminal connected to the second electrode of the battery,
the first winding and the second winding are connected in series between the first power terminal and the third power terminal,
the third winding is connected between the second power terminal and the fourth power terminal,
the first winding and the third winding form a common-mode inductor configured to suppress a common-mode noise current flowing between the first power terminal and the third power terminal as well as between the second power terminal and the fourth power terminal,
the first winding, the second winding, and the third winding form a differential-mode inductor configured to suppress a differential-mode noise current flowing between the first power terminal and the third power terminal as well as between the second power terminal and the fourth power terminal,
the first winding, the second winding, the third winding, the first smoothing capacitor, and the second smoothing capacitor form a filter circuit,
the resistive element is connected in parallel across at least one of the first winding, the second winding, or the third winding in the filter circuit, and is configured to suppress a resonance in the filter circuit,
the first smoothing capacitor and the second smoothing capacitor are included in the filter component,
a capacitance of the first smoothing capacitor is larger than a capacitance of the second smoothing capacitor, and
a frequency of the resonance in the filter circuit is set based on the capacitance of the second smoothing capacitor and an inductance of the differential-mode inductor.

7. The filter component according to claim 6, wherein
the resistive element is connected in parallel to the second winding between the first power terminal and the third power terminal.

8. The filter component according to claim 6, wherein
the first winding is wound around either the outer core or the short-circuit core,
the second winding is wound around the short-circuit core, and
the third winding is wound around at least one of the outer core or the short-circuit core.

9. The filter component according to claim 6, wherein
an electrical resistance of the resistive element increases along with a rise in a temperature of the resistive element.
